(19) United States
(12) Patent Application Publication
(10) Pub. No.: US 2003/0089997 A1
(43) Pub. Date: May 15, 2003

(54) Tiedowns connected to kerf regions and edge seals

(76) Inventors: Egon Mergenthaler, Iphofen (DE); Helge Altfeld, Munich (DE)

Correspondence Address: FISH & RICHARDSON PC, 225 FRANKLIN ST, BOSTON, MA, 02110, US

(21) Appl. No.: 10/037,213

(22) Filed: Nov. 9, 2001

(51) Int. Cl. H01L 23/053; H01L 23/12; H01L 23/48; H01L 23/52; H01L 29/40

(52) U.S. Cl. 257/774; 257/758; 257/700; 257/701

(57) ABSTRACT

A tiedown structure including a semiconductor substrate having a chip formed thereon, a kerf region, and a conductive connector forming a connection between the chip and the kerf region. Alternatively, the conductive connector connects an edge seal surrounding the chip and a chip portion. A method for forming a semiconductor structure includes forming a device on a chip, defining a kerf proximate the chip, and forming a conductive connector that connects the device and the kerf. An end of the conductive connector is removed by sawing, etching, or focused ion beam milling. A method for forming a semiconductor structure includes forming a chip on a semiconductor substrate, the chip including a device; forming an edge seal along a perimeter of the chip; and forming a conductive connector that connects the edge seal and the device. A conductive connector portion is removed by etching or focused ion beam milling.

### TECHNICAL FIELD

This invention relates generally to semiconductor chip fabrication and, more particularly, to tiedown structures in such.

### BACKGROUND

A conventional tiedown diode includes a metal line or antenna having one end in electrical contact with a device portion, such as a transistor gate on a chip, and another end in contact with a diffused region on the same chip. The tiedown diode thus grounds the transistor, protecting the transistor from irreversible damage that can be caused by ion overloading during plasma etching processes.

Conventional tiedown diodes are placed in those areas of the chip where the ratio of the metal wiring, i.e., the area of interconnect wiring, to the area of the gate is too large. This ratio being too large means that the amount of metal interconnection area can overload with ions during processing. The problem of ion overload is resolved as follows. In a p-type substrate, in an area with interconnect wiring positively charged during processing, an n-type diffused region can be provided for grounding a gate of a transistor with a conductive connection, called a tiedown. The conductive connection, together with pn diode formed by the n-type diffused region and p-type substrate, is called a “tiedown diode.” The placement of this diode ensures that the ion load while processing can be reduced by reverse biased leakage currents from the conductive connection through the diode.

The diode will not interfere with chip functionality by conducting current during device operation, if the metal wiring has a positive potential on the n-side of the pn interface. Accumulation of positive charge carriers at the n-type diffused region prevents current flow through the diode pn-interface. During device operation, therefore, a positive potential in this metal wiring causes the reverse bias condition of the diode. Thus, tiedown diodes on p-type substrates are used in those areas of the chip where the potential on the metal interconnections is positive.

Conventional tiedown diodes cannot be used, however, in chip areas where the metal interconnections have a negative potential during the operation of the chip. Forming a tiedown for a metal interconnect having a negative charge during device operation requires substantial silicon real estate. A tiedown should be connected to a diode so as to operate in reverse bias mode. Otherwise, if a negatively charged metal interconnection net is connected in the way described above for a positively-charged metal net, the tiedown diode will operate in a forward bias mode and cause a short to ground during device operation. In the latter case, therefore, time-consuming layout modifications are necessary to avoid this type of connection. This is not an efficient solution in terms of usage of chip area.

As noted above, space constraints limit the formation of conventional tiedown diodes for metal interconnects which have a negative potential on p-type substrate during device operation. Further, problems also occur during chip operation with tiedowns formed with positively charged metal interconnects because the tiedown diodes form capacitors coupled to ground, which can cause signal delays. In addition, a critical situation can occur when the positively charged interconnect is loaded with a negative potential for short time. This negative charge can occur, for example, during the booting up of a chip. The presence of the negative charge briefly subjects the diode to a forward bias condition that allows current to flow from the interconnect through the diode to ground potential during device operation, possibly leading to a chip malfunction.

### SUMMARY

In an aspect of the invention, a tiedown structure includes a semiconductor substrate having a chip formed thereon, a kerf region proximate the chip, and a conductive connector forming a connection between the chip and the kerf region.

Some embodiments include the following features. The tiedown structure has an edge seal along an outer perimeter of the chip, and the conductive connector crosses the edge seal. The conductive connector is not in electrical communication with the edge seal. The conductive connector is a metal line. The chip includes a device and the conductive connector is in electrical communication with the device and the kerf region. The conductive connector is in electrical communication with ground potential in the kerf region.

In another aspect of the invention, a tiedown structure includes a semiconductor substrate having a chip formed thereon, an edge seal along an outer perimeter of the chip, and a conductive connector forming a connection between the edge seal and a portion of the chip.

Some embodiments include the following features. The chip includes a device and the conductive connector is in electrical communication with the device and the edge seal. The conductive connector is a metal line.

In accordance with still another aspect of the invention, a method for forming a semiconductor structure includes forming a device on a chip, defining a kerf proximate the chip, and forming a conductive connector, the conductive connector connecting the device and the kerf.

Some embodiments include the following features. Forming a conductive connector includes forming a metal line. The conductive connector connecting the device and the kerf connects the device to ground potential in the kerf. An end of the conductive connector is removed from the kerf. Removing an end of the conductive connector includes sawing through the kerf, etching, or focused ion beam milling.

In another aspect of the invention, a method for forming a semiconductor structure includes forming a chip on a semiconductor substrate, the chip including a device; forming an edge seal along an outer perimeter of the chip; and forming a conductive connector, the conductive connector connecting the edge seal and the device.

Some embodiments include the following features. Forming a conductive connector includes forming a metal line. The conductive connector connecting the edge seal and the device connects the device to ground potential in the edge seal.

A portion of the conductive connector is removed. The portion of the conductive connector that is removed is between the edge seal and the device. The portion of the conductive connector is removed by etching or by focused ion beam milling.

The tiedown structures are connected to the kerf or edge seal structures, and, therefore, do not consume significant chip space.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIGS. 1A-9 are cross-sectional and top views of a tiedown and edge seal structure at various stages of fabrication.

FIG. 10 is a cross-sectional view of a tiedown and edge seal taken along line 10-10 in FIG. 7.

FIGS. 11-12 are cross-sectional views of the tiedown and edge seal of FIG. 10 at further stages of fabrication.

FIG. 13 is a cross-sectional view of an edge seal without a tiedown taken along line 13-13 in FIG. 7.

FIGS. 14-15 are cross-sectional views of the edge seal of FIG. 13 at further stages of fabrication.

FIG. 16 is a top view of an alternative tiedown and edge seal structure in which the tiedown is connected to an edge seal structure.

FIG. 17 is a cross-sectional view of the tiedown and edge seal of FIG. 16, taken along line 17-17 in FIG. 16.

FIG. 18 is a cross-sectional view of the tiedown and edge seal of FIG. 17 at further stages of fabrication.

FIG. 19 is a cross-sectional view of the tiedown and edge seal structure of FIG. 12 after removal of the tiedown connection to the kerf region by sawing.

FIG. 20 is cross-sectional view of the tiedown and edge seal structure of FIG. 12 after removal of the tiedown connection to the kerf region by etching or focused ion beam milling.

FIG. 21 is a cross-sectional view of the tiedown and edge seal structure of FIG. 18 after removal of a portion of the tiedown by etching or focused ion beam milling.

Like reference symbols in the various drawings indicate like elements.

### DETAILED DESCRIPTION

Structures and methods are provided for forming tiedowns having connections to ground in kerf regions (defined below) and edge seals. These tiedowns protect chip elements from charge overload during processing, without consuming significant chip space.

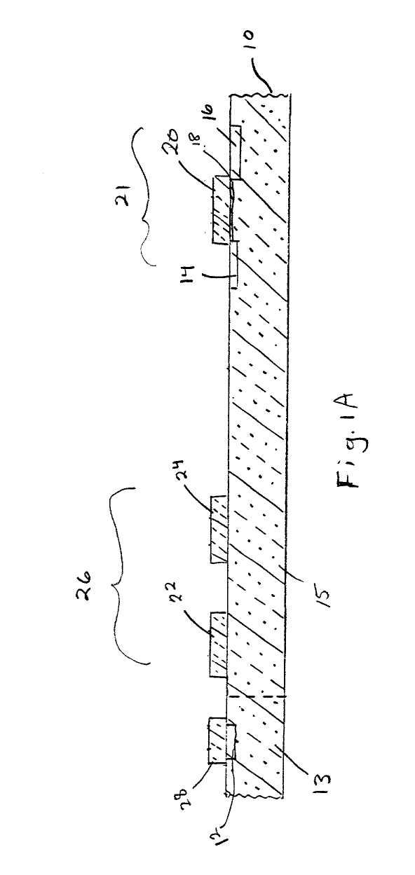

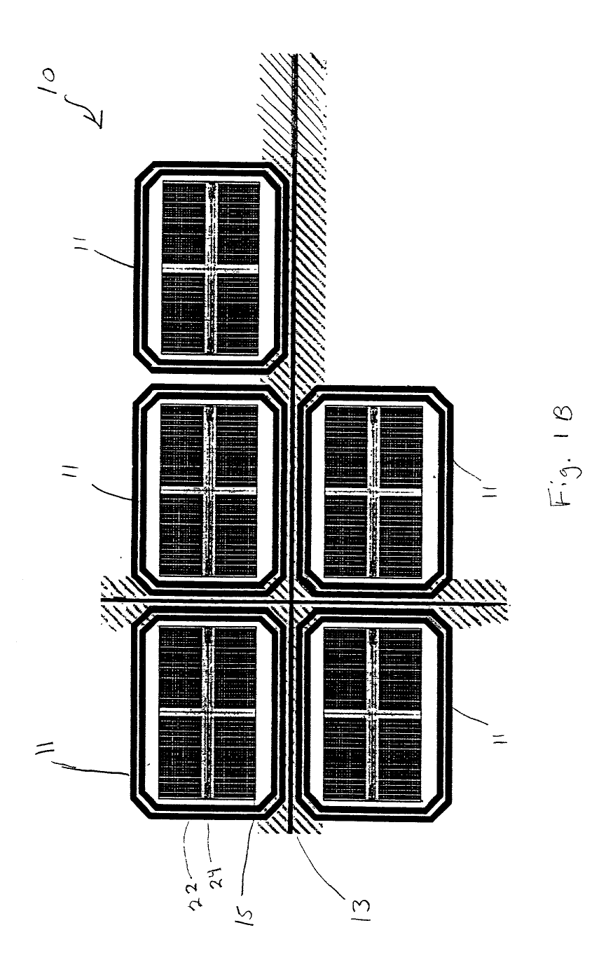

Referring to FIGS. 1A and 1B, a semiconductor substrate 10, is made of, e.g., p-type silicon. A kerf region 13 is proximate a chip 11 formed in substrate 10. Kerf region 13 is the area through which a saw cuts at the end of processing to singulate chip 11. A p-type diffused region 12 is formed by ion implantation of, for example, boron ions, in kerf region 13.

A chip portion 15 has an n-type source 14 and an n-type drain 16 region, formed by ion implantation proximate a gate dielectric 18, such as silicon dioxide. A gate electrode material, such as polysilicon, is deposited to form a layer (not shown) over substrate 10. The gate electrode material may be patterned by photolithography and dry etching to define a gate electrode 20, thereby forming a transistor 21 having gate electrode 20 and source and drain regions 14, 16. The gate electrode material defines first and second conductive lines 22, 24 in an edge seal 26. Edge seal 26 is formed along an outer perimeter of chip 11. The gate electrode material also defines a first contact 28 to p-type region 12 in kerf 13.

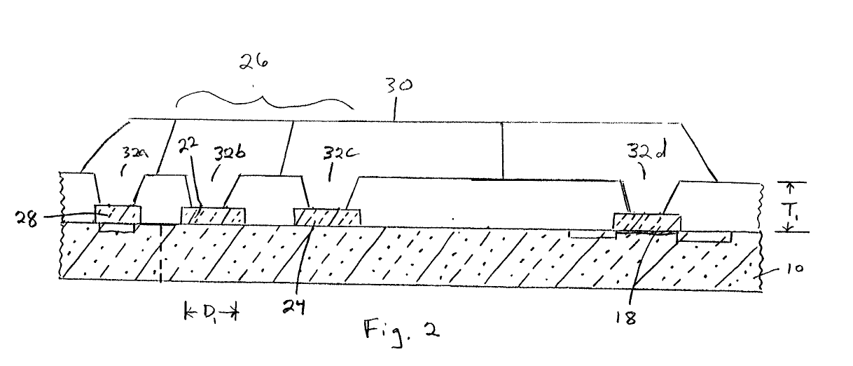

Referring to FIG. 2, a first interlevel dielectric layer 30 is deposited over substrate 10 by a deposition method, such as plasma enhanced chemical vapor deposition (PECVD). First interlevel dielectric layer 30 is, for example, a silicon dioxide layer having a thickness T₁ of 300 nanometers (nm). First layer dielectric vias 32a-32d are defined in first interlevel dielectric layer 30 by photolithography and dry etching. First layer dielectric vias 32a-32d expose top surfaces of first contact 28, first and second conductive lines 22, 24 of edge seal 26, and gate electrode 18, respectively. Each of first layer dielectric vias 32a-32d has a top diameter D₁ of, for example, 50 nm.

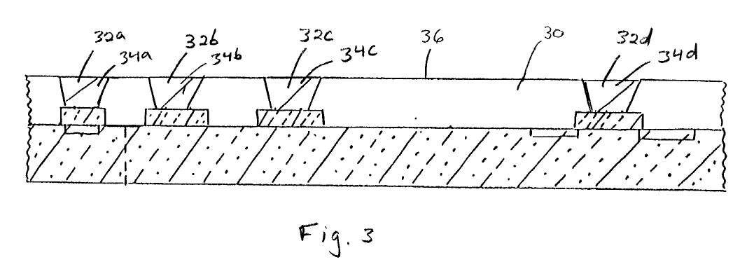

Referring to FIG. 3, each one of vias 32a-32d is filled with a metal plug 34a-34d, respectively. Metal plugs 34a-34d are made of a metal such as tungsten, deposited by chemical vapor deposition (CVD) in a system such as the Endura® system, manufactured by Applied Materials, Inc., based in Santa Clara, Calif. Excess metal is removed by chemical mechanical polishing, to reveal a top surface 36 of first interlevel dielectric layer 30.

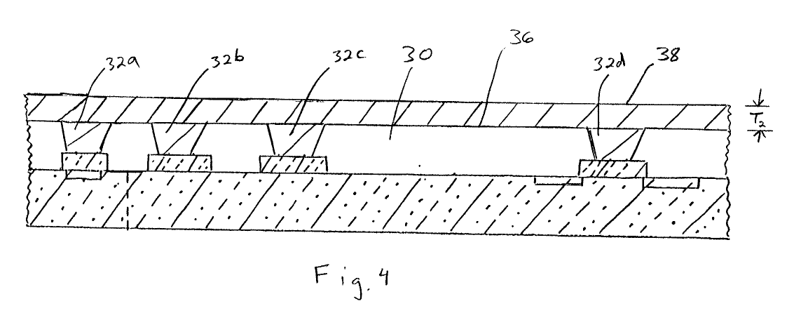

Referring to FIG. 4, a first metal layer 38 is deposited over top surface 36 of first interlevel dielectric layer 30 and metal plugs 32a-32d. First metal layer 38 is made of, e.g., aluminum and has a thickness T₂ of 200 nm.

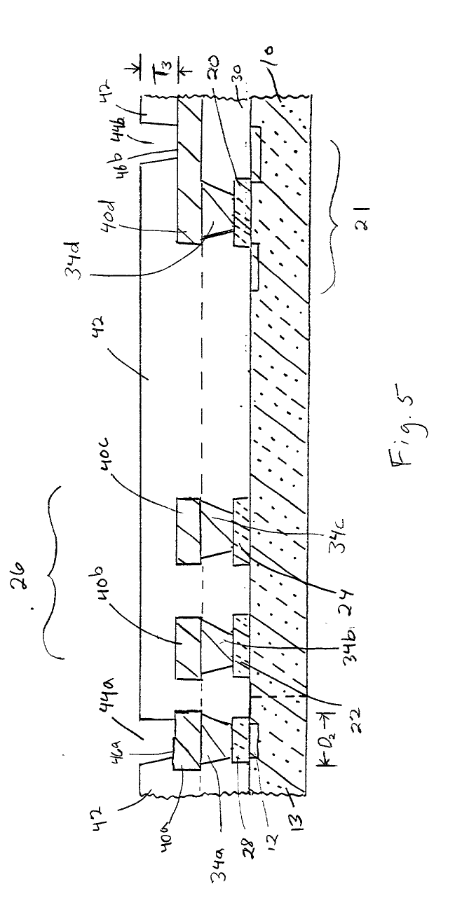

Referring also to FIG. 5, first metal layer 38 (shown in FIG. 4) is patterned by photolithography and dry etching to form a plurality of first level metal lines 40a-40d. One of the first level metal lines 40a is formed in kerf region 13 of substrate 10, in contact with metal plug 34a in first interlevel dielectric layer 30, and in electrical communication with first contact 28 and p-type region 12. Edge seal first level metal lines 40b, 40c are formed in the edge seal 26, in contact with metal plugs 34b, 34c in first interlevel dielectric layer 30 and in electrical communication with first and second conductive lines 22, 24, respectively. Layers in electrical communication are not necessarily in contact, but electrons can nevertheless pass between them. A fourth first level metal line 40d is formed over transistor 21, in contact with metal plug 34d and in electrical communication with gate electrode 20.

Subsequently, a second interlevel dielectric layer 42 is deposited over first level metal lines 40a-40d and first interlevel dielectric layer 30 by a deposition method, such as PECVD. Second interlevel dielectric layer 42 is, for example, a silicon dioxide layer, and it has a thickness T₃ over first level metal line 40d of, for example, 300 nm. Second layer dielectric vias 44a, 44b are formed in second interlevel dielectric layer 42 by photolithography and dry etching, and have a top diameter D₂ of, for example, 50 nm. Second layer dielectric vias 44a, 44b expose a top surface 46a of first level metal line 40a in the kerf region 13, and a top surface 46b of first level metal line 40d in the transistor 21 region, respectively.

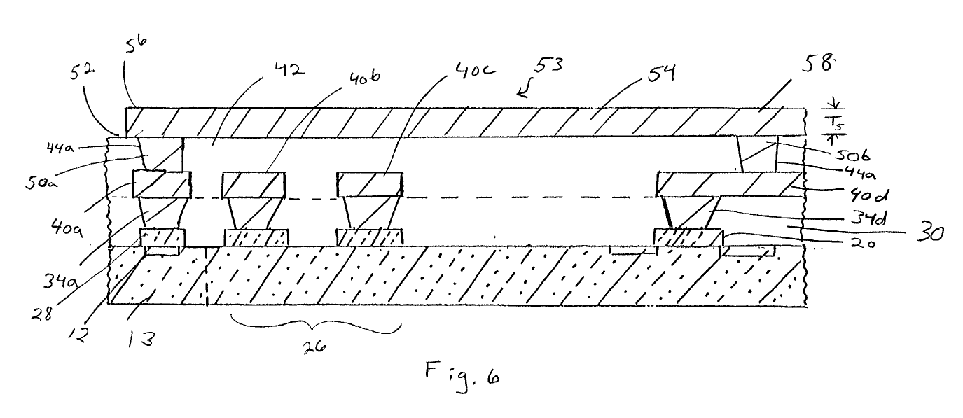

Referring to FIG. 6, second layer dielectric vias 44a, 44b are filled with metal plugs 50a, 50b, respectively. Metal plugs 50a, 50b may be made of tungsten, deposited by CVD. Excess metal may be removed by chemical mechanical polishing to expose a top surface 52 of second interlevel dielectric layer 42. Subsequently, a metal, such as aluminum, is deposited on top surface 52 of second interlevel dielectric layer 42 and over metal plugs 50a, 50b to form a second metal layer (not shown). The metal is patterned by photolithography and dry etching to form a conductive connector 54.

A tiedown structure 53 includes conductive connector 54 that, at a first end 56, contacts metal plug 50a in second interlevel dielectric layer 42 and is in electrical communication with first level metal line 40a in kerf region 13, metal plug 34a in first dielectric layer 30, first contact 28, and p-type region 12. Conductive connector 54, at a second end 58, contacts metal plug 50b and is in electrical communication with first level metal line 40d, metal plug 34d in first interlevel dielectric layer 30, and gate electrode 20. Conductive connector 54 passes through edge seal 26 without making electrical contact to underlying edge seal first level metal lines 40b, 40c. Tiedown 54 has a thickness T₅ of, for example, 200 nm and is made of aluminum in this embodiment.

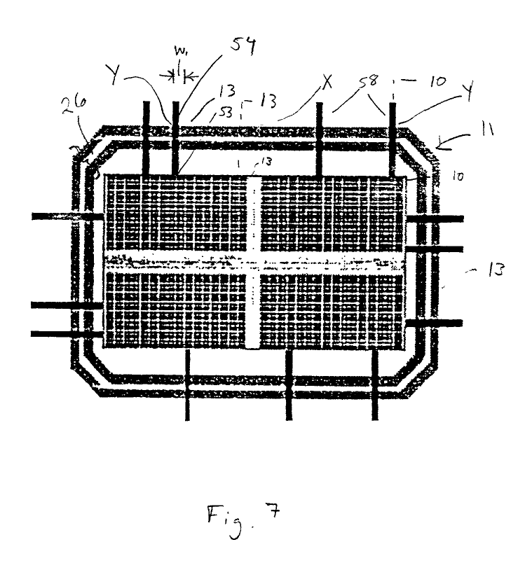

Referring to FIG. 7, conductive connector 54 has a width W₁ of, for example, 100 nm.

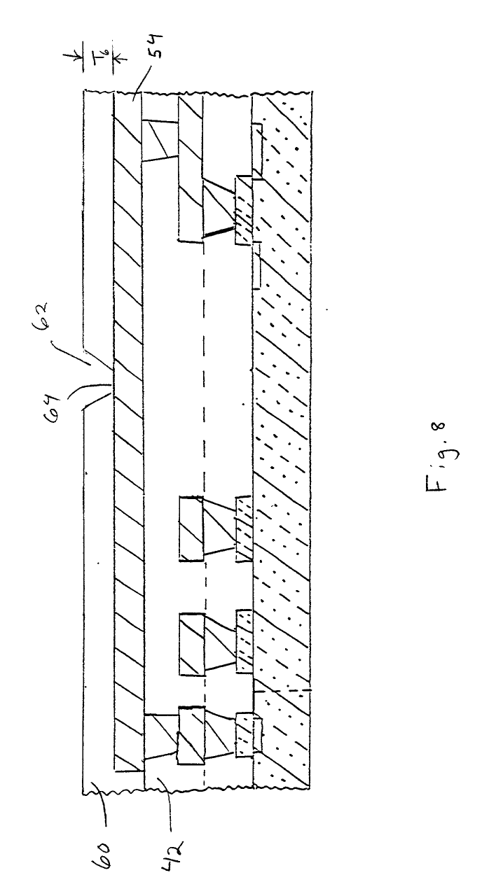

Referring to FIG. 8, a third interlevel dielectric layer 60 is deposited over conductive connector 54 and second interlevel dielectric layer 42 by a deposition method, such as PECVD. Third interlevel dielectric layer 60 may be a dielectric such as silicon dioxide, and it has a thickness T₆ over conductive connector 54 of, for example, 300 nm. A third layer dielectric via 62 is formed in third interlevel dielectric layer 60 by photolithography and dry etching. Third layer dielectric via 62 exposes a top surface 64 of conductive connector 54.

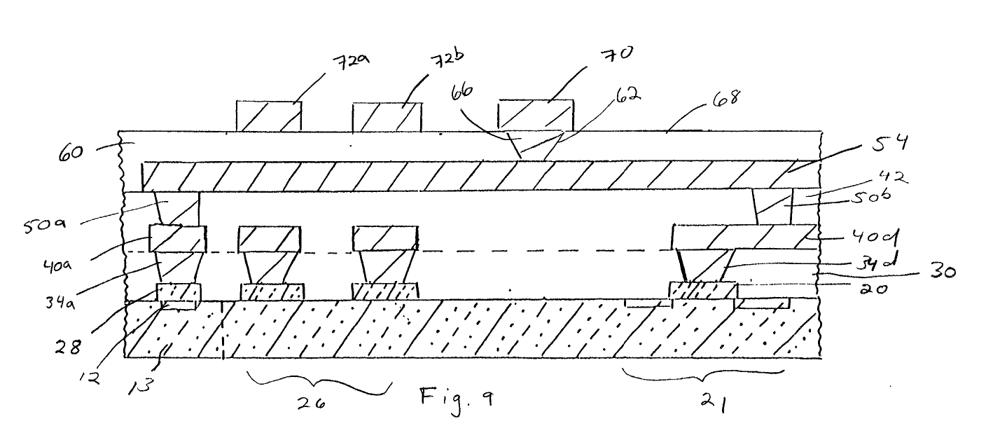

Referring to FIG. 9, third layer dielectric via 62 is filled with a metal plug 66 that is made of tungsten, deposited by CVD. Excess metal may be removed by chemical mechanical polishing to expose a top surface 68 of third interlevel dielectric layer 60. A third layer of metal, such as aluminum, is deposited on top surface 68 of third interlevel dielectric layer 60 and over metal plug 66 to form a layer (not shown). The third layer of metal is patterned by photolithography and dry etching to form a third level metal line 70 over metal plug 66 in third layer dielectric 60 and to form third level metal lines 72a, 72b in edge seal 26. Third level metal line 70 contacts metal plug 66 and is in electrical communication with both kerf region 13 and transistor 21. In particular, third level metal line 70 is in electrical communication with conductive connector 54, metal plugs 50a, 50b in second interlevel dielectric layer 42, first level metal line 40a in kerf region 13, metal plug 34a in first interlevel dielectric layer 30, first contact 28, and p-type region 12, as well as with first level metal line 40d, metal plug 34d in first interlevel dielectric layer 30, and gate electrode 20. Third level metal lines 72a, 72b in edge seal 26, on the other hand, are not in electrical communication with underlying conductive layers, including conductive connector 54.

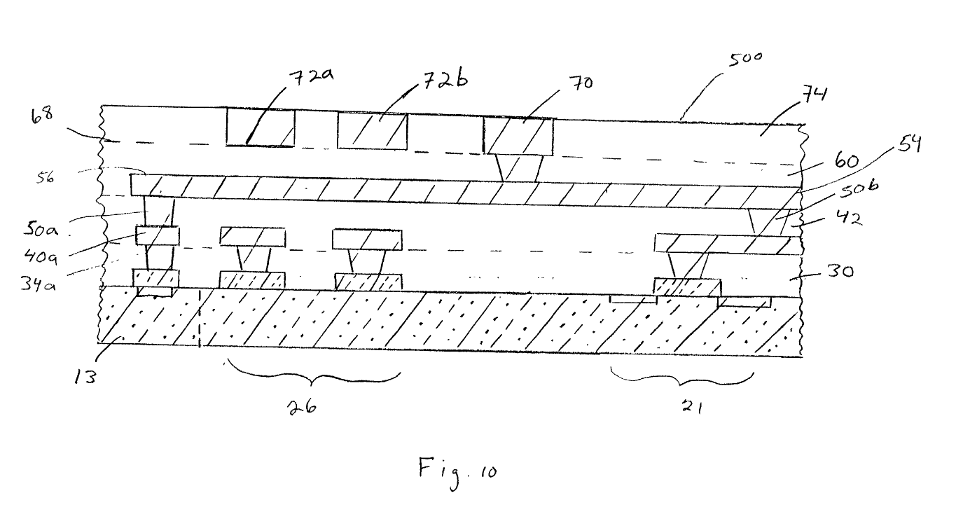

Referring to FIG. 10, a fourth interlevel dielectric layer 74 is deposited over top surface 68 of third interlevel dielectric layer 60, and polished back by chemical mechanical polishing to form a flat top surface 500.

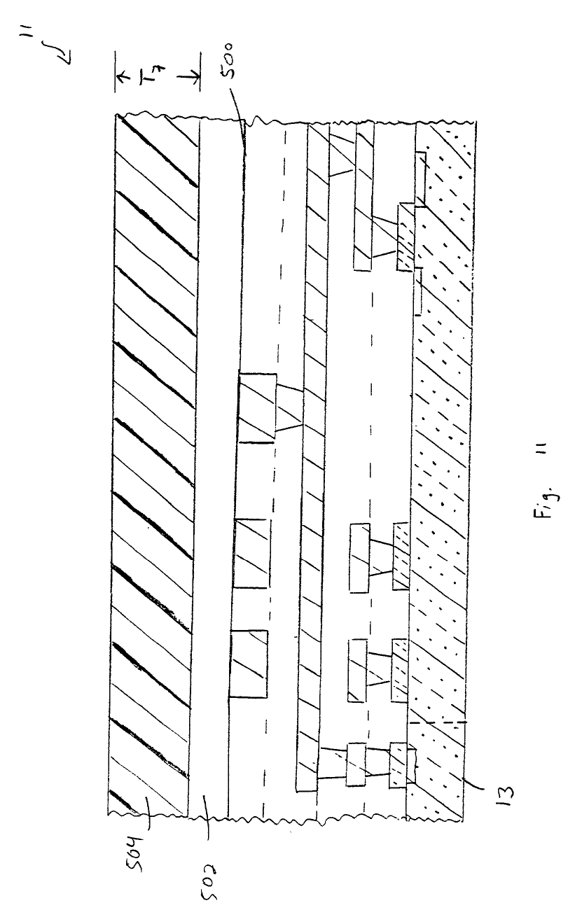

Referring to FIG. 11, chip 11 and kerf 13 may be encapsulated with an oxynitride film 502, which is deposited on flat top surface 500. Then, a polyimide layer 504 is deposited over oxynitride film 502. Polyimide layer has a thickness T₇ of, for example, 6 microns (μm).

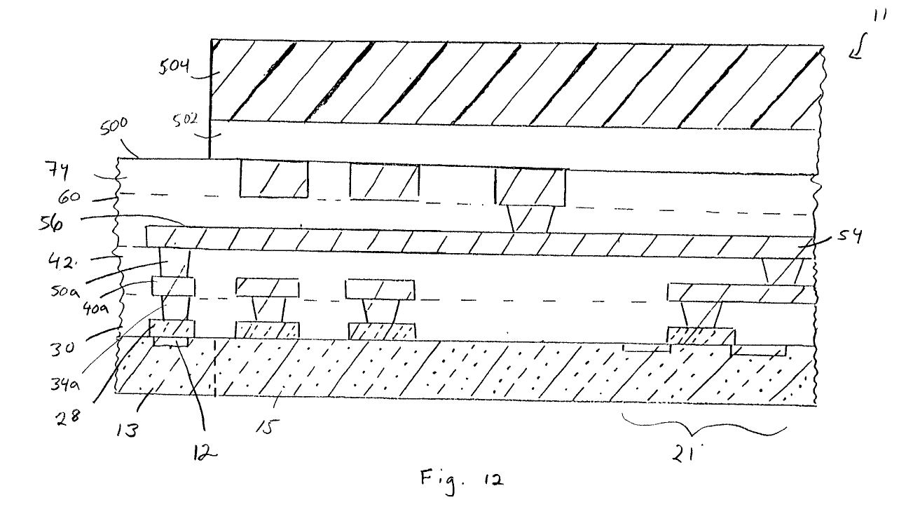

Referring to FIG. 12, a portion of polyimide layer 504 and a portion of oxynitride film 502 are removed to expose a portion of flat top surface 500 of fourth interlevel dielectric layer 74 over kerf region 13.

Referring to FIGS. 7, 10, and 13, the layer structure in edge seal 26 varies at point X (FIG. 7) where conductive connector 54 does not cross edge seal 26 from point Y where conductive connector 54 crosses edge seal 26. More specifically, the layer structure varies in the placement of vias in second interlevel dielectric layer 42 and third interlevel dielectric layer 60. The layer structure at point Y where conductive connector 54 crosses edge seal 26 has been described above, with reference to FIG. 10. At point Y, no vias or metal plugs are formed proximate conductive connector 54 in edge seal 26.

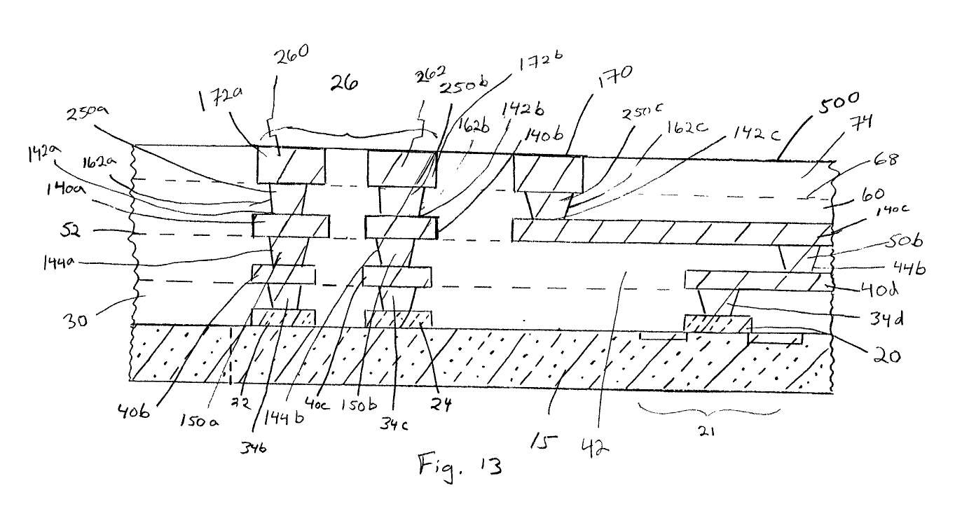

At point X (FIG. 13), where conductive connector 54 does not cross edge seal 26, first and second vias 144a, 144b are formed in second interlevel dielectric layer 42 at edge seal 26 at substantially the same time via 44b is formed in second interlevel dielectric layer 42.

Subsequently, first and second vias 144a, 144b are filled with metal plugs 150a, 150b at substantially the same time via 44b is filled with metal plug 50b, as described above in reference to FIG. 6. After the formation of metal plugs 50b, 150a, 150b, metal is deposited on top surface 52 of second interlevel dielectric layer 42 and over metal plugs 50b, 150a, 150b to form a second metal layer (not shown), and is patterned by photolithography and dry etching to form edge seal second level metal lines 140a, 140b in edge seal 26 and second level metal line 140c over transistor 21. Edge seal second level metal lines 140a, 140b contact metal plugs 150a, 150b respectively, and are in electrical communication with edge seal first level metal lines 40b, 40c, metal plugs 34b, 34c, and first and second conductive lines 22, 24 respectively. Second level metal line 140c over transistor 21 contacts metal plug 44b and is in electrical communication with first level metal line 40d, metal plug 34d in first interlevel dielectric layer 30, and gate electrode 20.

Subsequent to the definition of edge seal second level metal lines 140a, 140b and second level metal line 140c over transistor 21, third interlevel dielectric layer 60 is formed, as described above with reference to FIG. 8. Third layer dielectric vias 162a-162c are formed in third interlevel dielectric layer 60 by photolithography and dry etching. Third layer dielectric vias 162a, 162b are formed in the edge seal region 26 and expose a top surface 142a, 142b of edge seal second level metal lines 140a, 140b, respectively. Third layer dielectric via 162c is formed over chip region 15, and it exposes a top surface 142c of second level metal line 140c.

Third layer dielectric vias 162a-162c are filled with metal plugs 250a-250c, respectively, as described above with reference to FIG. 9. Subsequently, the third layer of metal is deposited on top surface 68 of third interlevel dielectric layer 60 and is patterned by photolithography and dry etching to form a third level metal line 170 over metal plug 250c and third level metal lines 172a, 172b in edge seal 26. Third level metal line 170 contacts metal plug 250c and is in electrical communication with second level metal line 140c over transistor 21, metal plug 50b, first level metal line 40d over transistor 21, metal plug 34d, and gate electrode 20. Third level metal lines 172a, 172b are in contact with metal plugs 250a, 250b respectively.

Fourth dielectric layer 74 is deposited over top surface 68 of third interlevel dielectric layer 60 and polished back by chemical mechanical polishing to form flat top surface 500.

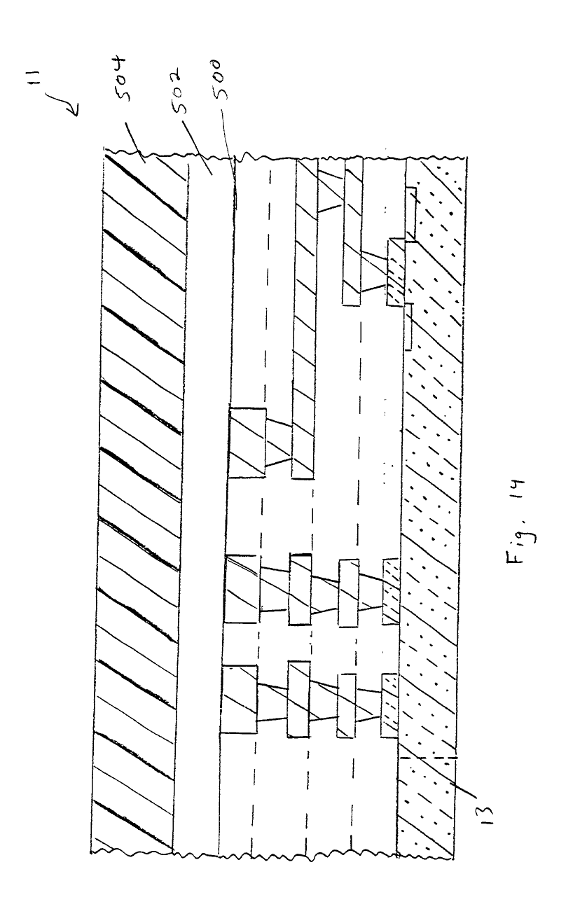

Referring to FIG. 14, chip 11 and kerf 13 are encapsulated with a silicon oxynitride film 502, which is deposited on flat top surface 500. Then, polyimide layer 504 is deposited over silicon oxynitride film 502.

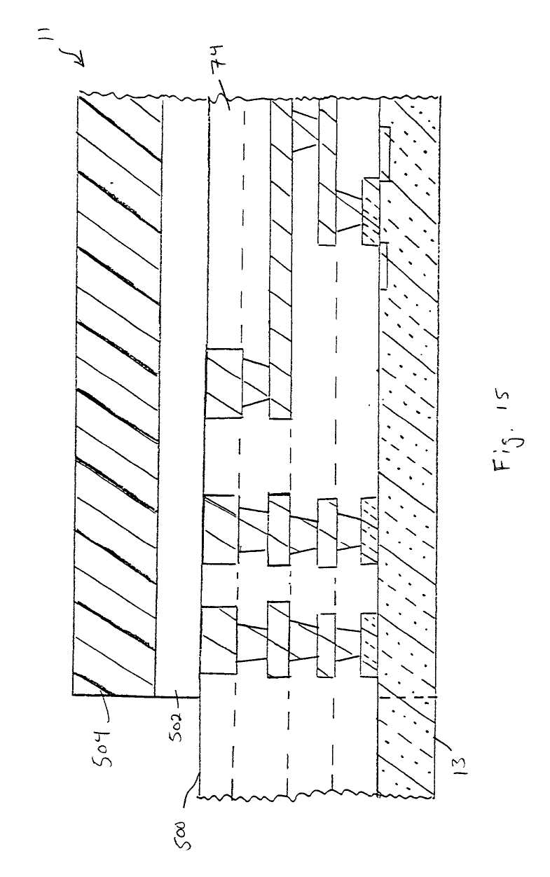

Referring to FIG. 15, a portion of polyimide layer 504 and a portion of silicon oxynitride film 502 are removed to expose a portion of flat top surface 500 of fourth interlevel dielectric layer 74 over kerf region 13.

Referring to FIG. 1B, FIG. 7, and FIG. 13, edge seal 26, at point X where conductive connector 54 does not cross edge seal 26, has two parallel first and second conductive structures 260, 262, respectively. First and second conductive structures 260, 262 include first and second conductive lines 22, 24, metal plugs 34b, 34c in first interlevel dielectric layer 30, first level metal lines 40b, 40c, metal plugs 150a, 150b in second interlevel dielectric layer 42, second level metal lines 140a, 140b, metal plugs 250a, 250b in third interlevel dielectric layer 60, and third level metal lines 172a, 172b. First and second conductive structures 260, 262 surround chip 11, thereby providing mechanical support and protecting chip 11 from breaking during singulation.

During processing subsequent to conductive connector 54 formation, tiedown 53 grounds transistor 21 by forming an electrical connection between gate electrode 20 of transistor 21 and ground, i.e. p-type region 12 in kerf 13. This electrical connection prevents charge overloading of transistor 21 during processing steps, thereby preventing the irreversible damage of transistor 21.

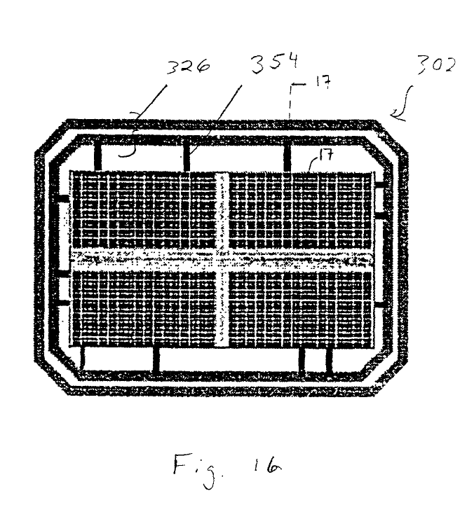

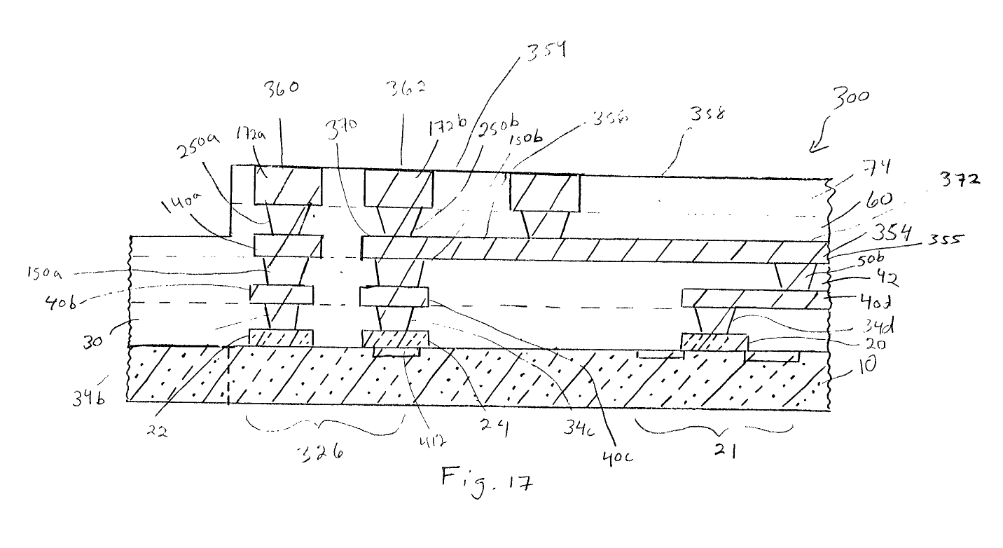

Referring to FIGS. 16 and 17, in an alternative embodiment, a structure 300 in chip 302 has a tiedown 354 connected to ground in an edge seal 326. Edge seal 326 has two conductive structures 360, 362 which include first and second conductive lines 22, 24, metal plugs 34b, 34c in first interlevel dielectric layer 30, first level metal lines 40b, 40c, metal plugs 150a, 150b in second interlevel dielectric layer 42, second level metal line 140a and a conductive connector 355, metal plugs 250a, 250b in third interlevel dielectric layer 60, and third level metal lines 172a, 172b, respectively. Conductive structure 362 is in electrical communication with a p-type region 412 formed in substrate 10 in edge seal region 326.

Tiedown 354 includes conductive connector 355 that, at a first end 370, is in electrical communication with edge seal structure 362, including p-type region 412. At its second end 372, conductive connector 355 contacts metal plug 50b in second interlevel dielectric layer 42 and is in electrical communication with first level metal line 40d, metal plug 34d in first interlevel dielectric layer 30, and gate electrode 20.

The structure 300 having tiedown 354 connected to ground in edge seal 326 is fabricated with methods analogous to those used to fabricate tiedown 54 connected to ground in kerf region 13 in FIGS. 1a-10.

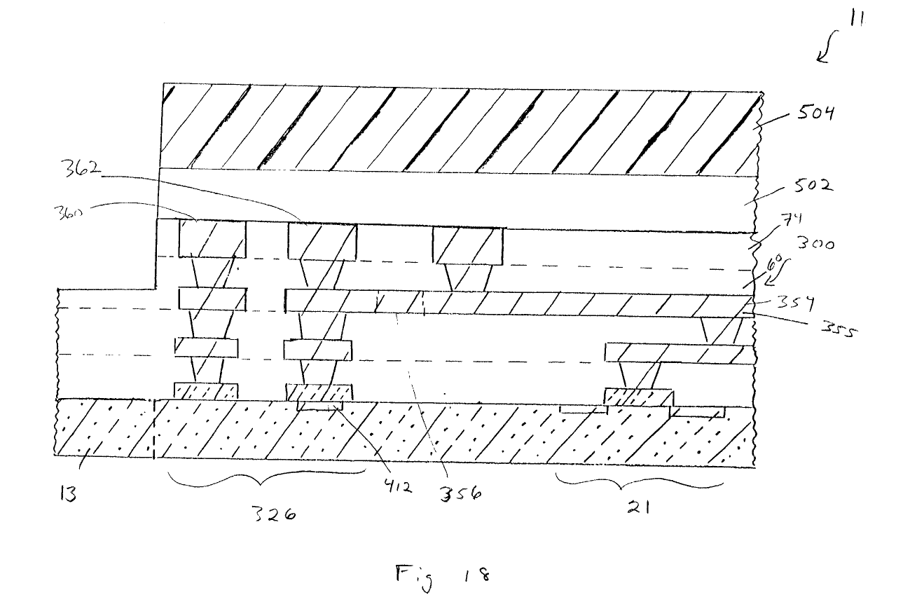

Referring to FIG. 18, structure 300 is covered with oxynitride film 502 and polyimide layer 504, and a portion of oxynitride film 502 and polyimide layer 504 is removed over kerf region 13.

During processing subsequent to tiedown 354 formation, tiedown 354 grounds transistor 21 by forming an electrical connection between gate electrode 20 of transistor 21 and ground, i.e. p-type region 412 in edge seal structure 362. This electrical connection prevents charge overloading of transistor 21 during processing steps, thereby preventing the irreversible damage of transistor 21.

After completion of fabrication of chip 11, tiedowns must be removed, including both tiedowns 54 which ground transistors 21 by connecting them to kerf regions 13 and tiedowns 354 which ground transistors 21 by connecting them to edge seal regions 26. Tiedowns 54, 354 must be removed to prevent them from providing short circuits to ground of transistors 21, thereby resulting in depletion of gate electrodes 20.

Tiedowns 54 connecting transistors 21 to the kerf region 13 can be removed in one of three methods: i) sawing; ii) etching; or iii) focused ion beam milling (FIB).

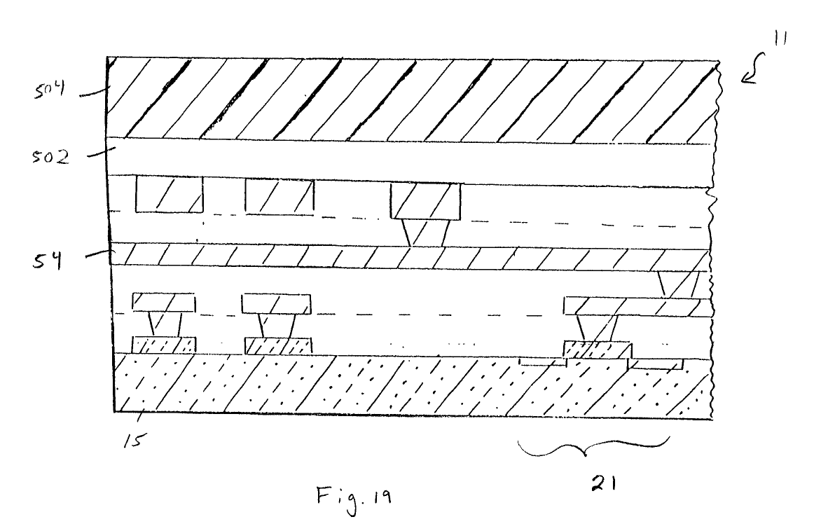

Referring to FIGS. 1B, 7, 12, and 19, tiedown 54 forms an electrical connection between transistor 21 and kerf region 13. This electrical connection is broken when chip 11 is singulated by sawing. Upon singulation, a saw blade (not shown) cuts through kerf region 13, thereby destroying the end 56 of tiedown 54 located in kerf region 13. The saw blade also destroys the other conductive layers in kerf region 13, i.e. metal plug 50a in second interlevel dielectric layer 42, first level metal line 40a in kerf region 13, metal plug 34a in first interlevel dielectric layer 30, and first contact 28, as well as portions of dielectric layers, i.e. first, second, third, and fourth level interdielectric layers 30, 42, 60, 74. After singulation of chip 11, therefore, transistor 21 is no longer connected to ground by means of tiedown 54, thereby preventing charge depletion during operation of transistor 21.

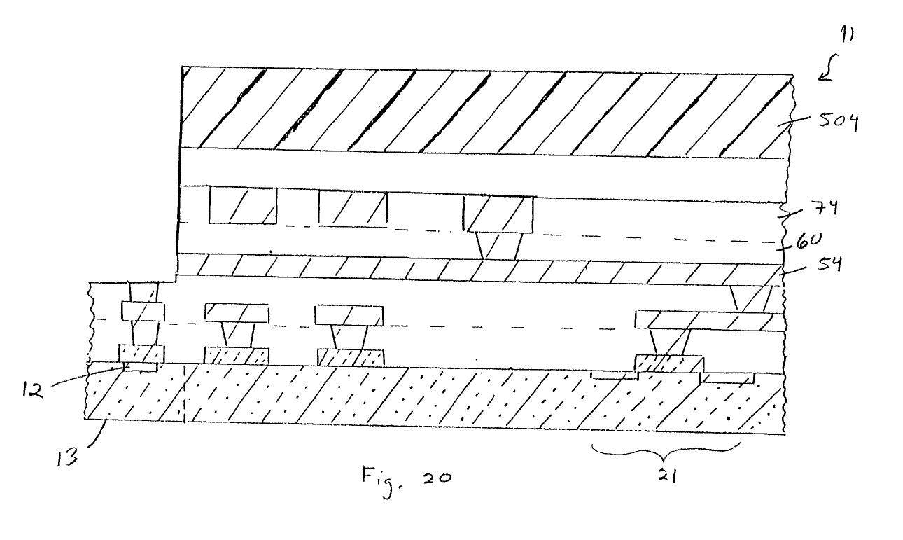

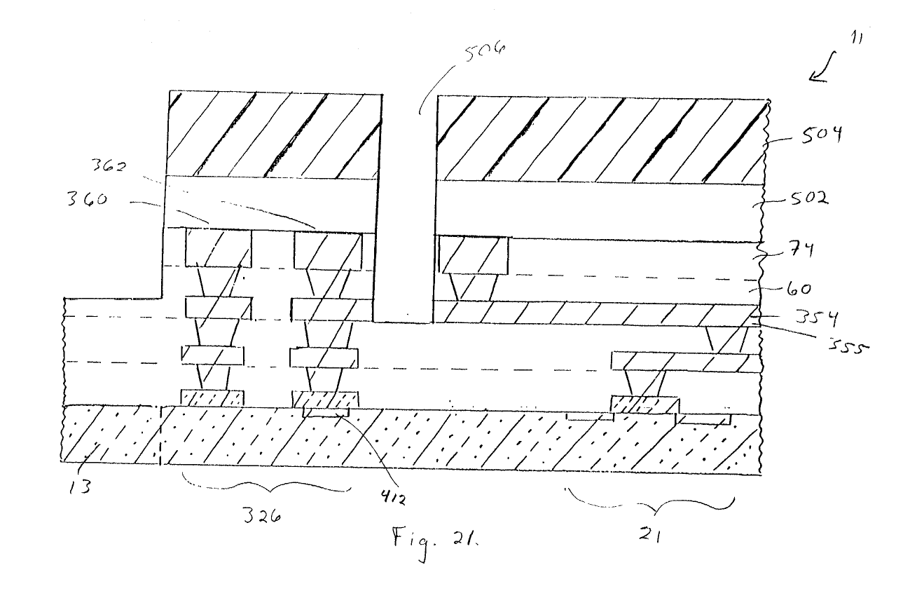

Alternatively, referring to FIGS. 12 and 20, after completion of fabrication of chip 11, the layers in kerf region 13 can be removed by etching to break the electrical connection of tiedown 54 between transistor 21 and p-type region 12 in kerf region 13. A photoresist mask (not shown) is formed to cover polyimide layer 504 to protect underlying layers of chip 11. Portions of some of the dielectric and metal layers in kerf region 13 are then removed by a process such as dry etching, using an etching system such as the TCP™ system, manufactured by Lam Research Corporation, based in Fremont, Calif. Different processing parameters are used to remove dielectric layers and metal layers. For example, a fluorine-based chemistry is used to etch off fourth interlevel dielectric layer 74 and third interlevel dielectric layer 60 over kerf region 13. A chlorine-based chemistry is used to etch off end 56 of tiedown 54. After these etches, transistor 21 is no longer connected to ground by tiedown 54, thereby preventing charge depletion during operation of transistor 21.

Referring again to FIG. 20, in an alternative embodiment, end 56 of tiedown 54 is removed by focused ion beam milling, using a system such as the Vectra™ 200, manufactured by FEI Company, based in Hillsboro, Oreg. The same parameters are used for the removal of dielectric and metal layers. Typical FIB processing parameters include milling with gallium ions having an energy of 30-50 kilo-electron-volts (keV) and a dosage of 100 picoCoulombs/square micrometer (pC/μ²). The focused ion beam removes portions of fourth interlevel dielectric 74, third interlevel dielectric 60, and end 56 of tiedown 54 in kerf region 13. After this focused ion beam milling is completed, transistor 21 is no longer connected to ground by tiedown 54, thereby preventing charge depletion during operation of transistor 21. Removal of a portion 56 by FIB results in a kerf region 13 structure equivalent to the kerf region 13 structure formed by removal of a portion 56 by etching, as described above.

Referring to FIGS. 18 and 21, tiedown 354 forms an electrical connection between a transistor 21 and a p-type region 412 in edge seal 326. Tiedown 354 connecting transistor 21 to the edge seal 326 can be removed in one of two methods: i) etching; and ii) focused ion beam milling.

After completion of fabrication of chip 11, the electrical connection between transistor 21 and p-type region 412 in conductive structure 362 in edge seal 326 can be removed by etching away a portion 356 of a conductive connector 355. A photoresist mask (not shown) is formed to cover polyimide layer 504 and kerf 13. The photoresist mask has an opening over portion 356 of conductive connector 355. A portion of polyimide layer 504 below the photoresist mask opening is removed by plasma etch tool, such as the P500 MXP, manufactured by Applied Materials, Inc. Portions of dielectric layers underneath the opening in the photoresist mask are then removed by a process such as dry etching with a fluorine-based chemistry, using an etching system such as the TCP™, manufactured by Lam Research Corporation. The dielectric layers from which portions are removed underneath the photoresist mask opening are fourth interlevel dielectric layer 74 and third interlevel dielectric layer 60. Upon removal of portions of these layers, a portion 356 of conductive connector 355 is exposed. Portion 356 is removed, for example, by a chlorine-based etch process in a TCP™, manufactured by Lam Research Corporation. After these etches, transistor 21 is no longer connected to ground by tiedown 354, thereby preventing charge depletion during operation of transistor 21.

In an alternative embodiment, after the completion of fabrication of chip 302, portion 356 of conductive connector 355 is removed by focused ion beam milling, using a system such as the Vectra™ 200, manufactured by FEI Company. The same parameters are used for the removal of dielectric and metal layers. Typical FIG processing parameters include milling with gallium ions having an energy of 30-50 keV and a dosage of 100 pC/μ². The focused ion beam removes portions of polyimide layer 504, oxynitride layer 502, fourth interlevel dielectric layer 74, third interlevel dielectric layer 60, and portion 356 of conductive connector 355. After this focused ion beam milling, transistor 21 is no longer connected to ground by tiedown 354, thereby preventing charge depletion during operation of transistor 21.

It is not necessary to fill an opening 506 that is formed by focused ion beam milling or by etching because subsequent packaging procedures provide adequate protection for chip 11.

A number of embodiments of the invention have been described. Nevertheless, it will be understood that various modifications may be made without departing from the spirit and scope of the invention. For example, the semiconductor substrate can have a device other than a transistor formed thereon, such as a diode or a resistor. Devices fabricated on n-type substrates with tiedown structures to n-type regions. Metal plugs can be made of a metal other than tungsten, such as aluminum. Metal lines can be formed from aluminum, titanium, copper, etc., as well as from various alloys. More or fewer metal levels and interlevel dielectric layers can be formed, depending on the chip design requirements. Vias can be formed by wet etching or a combination of wet and dry etching. Accordingly, other embodiments are within the scope of the following claims.

What is claimed is:

1. A tiedown structure, comprising:
a semiconductor substrate having a chip formed thereon;
a kerf region proximate the chip; and
a conductive connector forming a connection between the chip and the kerf region.

2. The tiedown structure of claim 1, further comprising:
an edge seal along an outer perimeter of the chip,
wherein the conductive connector crosses the edge seal.

3. The tiedown structure of claim 2, wherein the conductive connector is not in electrical communication with the edge seal.

4. The tiedown structure of claim 1, wherein the conductive connector is a metal line.

5. The tiedown structure of claim 1, wherein the chip comprises a device and the conductive connector is in electrical communication with the device and the kerf region.

6. The tiedown structure of claim 5, wherein the conductive connector is in electrical communication with ground potential in the kerf region.

7. A tiedown structure comprising:
a semiconductor substrate having a chip formed thereon;
an edge seal along an outer perimeter of the chip; and
a conductive connector forming a connection between the edge seal and a portion of the chip.

8. The tiedown structure claim 5, wherein the chip comprises a device and the conductive connector is in electrical communication with the device and the edge seal.

9. The tiedown structure of claim 7, wherein the conductive connector is a metal line.

10. A method for forming a semiconductor structure, comprising:
forming a device on a chip;
defining a kerf proximate the chip; and
forming a conductive connector, the conductive connector connecting the device and the kerf.

11. The method of claim 10, wherein forming a conductive connector comprises forming a metal line.

12. The method of claim 10, wherein the conductive connector connecting the device and the kerf connects the device to ground potential in the kerf.

13. The method of claim 10, further comprising:
removing an end of the conductive connector from the kerf.

14. The method of claim 13, wherein removing an end of the conductive connector comprises sawing through the kerf.

15. The method of claim 13, wherein removing an end of the conductive connector comprises etching.

16. The method of claim 13, wherein removing an end of the conductive connector comprises focused ion beam milling.

17. A method for forming a semiconductor structure, comprising:
forming a chip on a semiconductor substrate, the chip including a device;
forming an edge seal along an outer perimeter of the chip; and
forming a conductive connector, the conductive connector connecting the edge seal and the device.

18. The method of claim 17, wherein forming a conductive connector comprises forming a metal line.

19. The method of claim 17, wherein the conductive connector connecting the edge seal and the device connects the device to ground potential in the edge seal.

20. The method of claim 17, further comprising:
removing a portion of the conductive connector.

21. The method of claim 20, wherein removing the portion of the conductive connector comprises removing a portion of the conductive connector between the edge seal and the device.

22. The method of claim 21, wherein removing the portion of the conductive connector comprises etching.

23. The method of claim 21, wherein removing the portion of the conductive connector comprises focused ion beam milling.
